(19) United States
(12) Patent Application Publication
(10) Pub. No.: US 2023/0156961 A1
(43) Pub. Date: May 18, 2023

(54) TWO-PHASE IMMERSION COOLING DEVICE WITH MOVABLE SECOND CONDENSER

(71) Applicant: Fulian Precision Electronics (Tianjin) Co., LTD., Tianjin (CN)

(72) Inventors: WARM-HORNG YUAN, Houston, TX (US); Chun Wang, Houston, TX (US); SHAO-YI WEN, Houston, TX (US)

(21) Appl. No.: 17/674,085

(22) Filed: Feb. 17, 2022

(30) Foreign Application Priority Data
Nov. 17, 2021 (CN) 202122814921.X

(51) Int. Cl. H05K 7/20; F28F 27/02

(52) U.S. Cl. CPC H05K 7/203; F28F 27/02; F28F 2265/00; F28F 2265/18

(57) ABSTRACT

A two-phase immersion cooling device includes a tank, heating elements, a first condenser, and a lid. An accommodating cavity of the tank bottom accommodates a coolant. The heating elements are disposed in the accommodating cavity and immersed in the coolant. The first condenser is received in the accommodating cavity, located above the coolant and the heating elements, and disposed along sidewalls of the tank. At least one movable second condenser is fixed on the lid or a rear door and disposed in a cavity surrounded by the first condenser. The two-phase immersion cooling device increases the capacity of condensation heat transfer, and the condensation rate and the evaporation rate of the coolant in the tank are balanced, a pressure difference between an inside and an outside of the tank is reduced, a loss of coolant vapor is decreased, and a volume of the two-phase immersion cooling device is reduced.

### TECHNICAL FIELD

The present disclosure relates to temperature control, in particular to a two-phase immersion cooling device.

### BACKGROUND

With the rapid improvement of power and heat flux density of computer chips, internet of things, batteries of new energy vehicles, electronic devices, home digital electrical equipment, digital medical treatments, chips and electronic devices of edge computing, quantum computing, heating components of mechanical equipment and heating components of electronic equipment, the cooling technology of the heating components has also experienced rapid development from generation to generation. After the continuous development of passive cooling, enhanced air cooling, thermosyphon loop heat pipe cooling, liquid cooling, and single-phase immersion cooling technology, a two-phase immersion cooling method is one of the most promising and effective server cooling technologies.

The existing two-phase immersion cooling device includes a box body, a heating element, a coolant, and a first condenser. The heating element is contained in the lower part of the box body and immersed in the coolant. The first condenser is disposed along at least one side wall of a plurality of inner walls on the upper part of the box body. The first condenser is far away from an upper cavity surrounded by one or a plurality of side walls for the heating element to pass up and down. The coolant in the bottom of the box body absorbs the heat generated by the heating element and is boiled and gasified, thereby cooling the heating element. The coolant vapor rises to the upper part of the box body and is condensed on the first condenser, and the coolant condensate on the first condenser falls back into the accommodating cavity in the bottom of the box body under the action of gravity, so as to achieve the effective cooling of the heating element. However, a large amount of extremely expensive coolant may be lost by the existing two-phase immersion cooling device, and the first condenser is large in size with low compactness and high cost.

Therefore, improvement is desired.

### SUMMARY OF THE DISCLOSURE

The present disclosure provides a two-phase immersion cooling device with a movable second condenser, which can reduce the loss of the extremely expensive coolant and has high compactness of a box body with low cost.

The present disclosure provides a two-phase immersion cooling device with a movable second condenser, the two-phase immersion cooling device with the movable second condenser includes a box body, a plurality of heating elements, a first condenser, and a cover body. The box body includes a plurality of side walls connected to each other from top to bottom and a bottom wall. The bottom wall is connected to one end of each of the plurality of side walls, the plurality of side walls and the bottom wall jointly form an accommodating cavity, and a bottom of the accommodating cavity is configured to contain a coolant. The plurality of heating elements are disposed in the accommodating cavity and adapted to be immersed in the coolant. The first condenser is disposed along at least one side wall, the first condenser is received in the accommodating cavity and located above the coolant and the plurality of heating elements, and the first condenser is far away from a cavity surrounded by the plurality of side walls. The cover body covers the box body to seal the accommodating cavity and the cover body is expandable on the box body to expose the accommodating cavity to the exterior environment. At least one movable second condenser is fixedly disposed on the cover body or a rear door located on an upper part of the box body, the at least one movable second condenser is received in the upper cavity, and the at least one movable second condenser leaves the accommodating cavity with movement of the cover body or the rear door.

According to an embodiment of the present disclosure, the first condenser and the at least one movable second condenser are combined into a third condenser, the third condenser is disposed on the cover body or the rear door.

According to an embodiment of the present disclosure, the cover body is detachably or reversibly connected to the box body, or the rear door is detachably connected to the box body.

According to an embodiment of the present disclosure, the two-phase immersion cooling device with the movable second condenser further comprises a power support or a power mover, the power support is connected to the cover body and used to drive the opening or closing of the cover body, and the power mover is connected to the rear door and used to drive the opening or closing of the rear door.

According to an embodiment of the present disclosure, the first condenser comprises a first cooling water system, the at least one movable second condenser comprises a second cooling water system, the first cooling water system of the first condenser and the second cooling water system of the at least one movable second condenser are operated independently, in series or in parallel, respectively.

According to an embodiment of the present disclosure, both the first condenser and the at least one movable second condenser comprise an inlet of the cooling water and an outlet of the cooling water. The inlet of the cooling water and the outlet of the cooling water pass through the upper part of the side wall of the box body, the cover body, or the rear door.

According to an embodiment of the present disclosure, the two-phase immersion cooling device with the movable second condenser further comprises at least one sensor disposed in the accommodating cavity, the at least one sensor comprises at least one of a temperature sensor, a humidity sensor, a pressure sensor, a flow sensor, and a liquid level sensor, the at least one sensor is configured for sensing at least one of a vapor temperature, a liquid temperature, vapor humidity, a vapor pressure, a liquid level height of the coolant, an inlet temperature of the cooling water, an outlet temperature of the cooling water, and a flow rate of the cooling water of each of the first condenser and the at least one movable second condenser in the accommodating cavity.

According to an embodiment of the present disclosure, the liquid level sensor is disposed on the box body or in the box body, the liquid level sensor is connected to the accommodating cavity, and the liquid level sensor detects a liquid level height of the coolant.

According to an embodiment of the present disclosure, the two-phase immersion cooling device with the movable second condenser further comprises a controller, the controller is electrically connected to the at least one movable second condenser, the at least one sensor, and the first condenser. When the at least one sensor senses the vapor temperature in the accommodating cavity is higher than a preset temperature or the vapor pressure in the accommodating cavity is higher than a preset pressure, the controller controls and adjusts the inlet temperature and the flow rate of the cooling water in the at least one movable second condenser or in the first condenser.

According to an embodiment of the present disclosure, the two-phase immersion cooling device with the movable second condenser further comprises an alarm and a coolant management system, the controller is electrically connected to the alarm, and the coolant management system. When the liquid level height of the coolant detected by the liquid level sensor is lower than a preset height, the controller controls the alarm to give an alarm, and controls the coolant management system to replenish the coolant into the accommodating cavity.

According to an embodiment of the present disclosure, the coolant management system comprises an overflow weir plate, a liquid storage tank, a pump, a pipeline, a valve, and a filter.

According to an embodiment of the present disclosure, the plurality of heating elements comprises a server applied to a data center, a battery or an electronic device applied to a new energy vehicle, an electronic chip or a device applied to a home intelligent digital appliance, an electronic chip or an electronic device applied to a digital medical treatment, an electronic chip or electronic device for digital medical treatment, a chip and an electronic device for edge computing, a chip for quantum computing, and a heating component applied to mechanical equipment or electronic equipment.

According to an embodiment of the present disclosure, the two-phase immersion cooling device with the movable second condenser further comprises at least one double-faced socket hermetically disposed on the box body or the cover body.

According to an embodiment of the present disclosure, the two-phase immersion cooling device with the movable second condenser further comprises an extracting valve, the extracting valve is disposed on the box body or the cover body, the extracting valve is connected to a vacuum device to extract non-condensable vapor in the accommodating cavity. The vacuum device places the accommodating cavity in a closed vacuum state before the operation of the heating elements or after the installation, removal, repair, and maintenance of the heating elements, so as to ensure the first condenser and the movable second condenser in the accommodating cavity can operate efficiently without non-condensable vapor.

According to an embodiment of the present disclosure, the two-phase immersion cooling device with the movable second condenser further comprises a handle disposed on the cover body or the rear door.

According to an embodiment of the present disclosure, the two-phase immersion cooling device with the movable second condenser further comprises a supporting member, the supporting member is disposed on the bottom of the box body, and the supporting member is a supporting frame or a roller.

According to an embodiment of the present disclosure, the two-phase immersion cooling device with the movable second condenser comprises a safety valve, when the vapor pressure in the accommodating cavity is higher than a preset vapor pressure, the safety valve is opened until the vapor pressure in the accommodating cavity is lower than the preset vapor pressure.

According to an embodiment of the present disclosure, the at least one movable second condenser is any one of a U-shaped tube condenser, a straight tube condenser, and a snake tube condenser.

According to an embodiment of the present disclosure, the two-phase immersion cooling device with the movable second condenser comprises a pressure balance valve, when the vapor pressure in the accommodating cavity is lower than an atmospheric pressure, the pressure balance valve is opened until the vapor pressure in the accommodating cavity is equal to the atmospheric pressure.

In the two-phase immersion cooling device with the movable second condenser provided by the present disclosure, due to at least one movable second condenser is disposed in a cavity, the coolant vapor located in the cavity can be condensed down, the contact area between the coolant vapor and the condenser is increased, and the heat transfer capacity of the condenser is effectively improved, the condensation rate and the evaporation rate of the coolant in the box body tend to be balanced which reduce the continuous increase of temperature and pressure in the box body caused by the condensation rate being lower than the evaporation rate, the pressure difference inside and outside the box body is reduced, the leakage loss of extremely expensive coolant vapor is reduced, the height of the first condenser is reduced, the volume of the two-phase immersion cooling device is reduced, and the two-phase immersion cooling device is more compact with low cost.

### BRIEF DESCRIPTION OF THE DRAWINGS

FIG. 1 is a schematic diagram of a two-phase immersion cooling device with a movable second condenser according to an embodiment of the present disclosure.

FIG. 2 is a schematic diagram of a cover body of the two-phase immersion cooling device of FIG. 1 unfolded on a box body.

FIG. 3 is a sectional view along line of FIG. 1.

FIG. 4 is an exploded view of the cover body and the box body of the two-phase immersion cooling device of FIG. 1.

FIG. 5 is a schematic block diagram of a third condenser according to an embodiment of the present disclosure.

FIG. 6 is a schematic block diagram of some components of the two-phase immersion cooling device with the movable second condenser according to an embodiment of the present disclosure.

FIG. 7 is a schematic block diagram of a coolant management system according to an embodiment of the present disclosure.

### DETAILED DESCRIPTION

The following description is used to disclose the present disclosure so that those skilled in the art can implement the present disclosure. The preferred embodiments in the following description are only examples, and those skilled in the art can think of other obvious variations. The basic principles of the present disclosure defined in the following description can be applied to other embodiments, modifications, improvements, equivalents, and other technical solutions that do not deviate from the spirit and scope of the present disclosure.

It can be understood that the height of the box body in the present disclosure refers to the vertically-upward direction and perpendicular to the bottom wall of the box body.

Some embodiments of the present disclosure are described in detail below in combination with the accompanying drawings. Without conflict, the following embodiments and features in the embodiments may be combined or can replace each other.

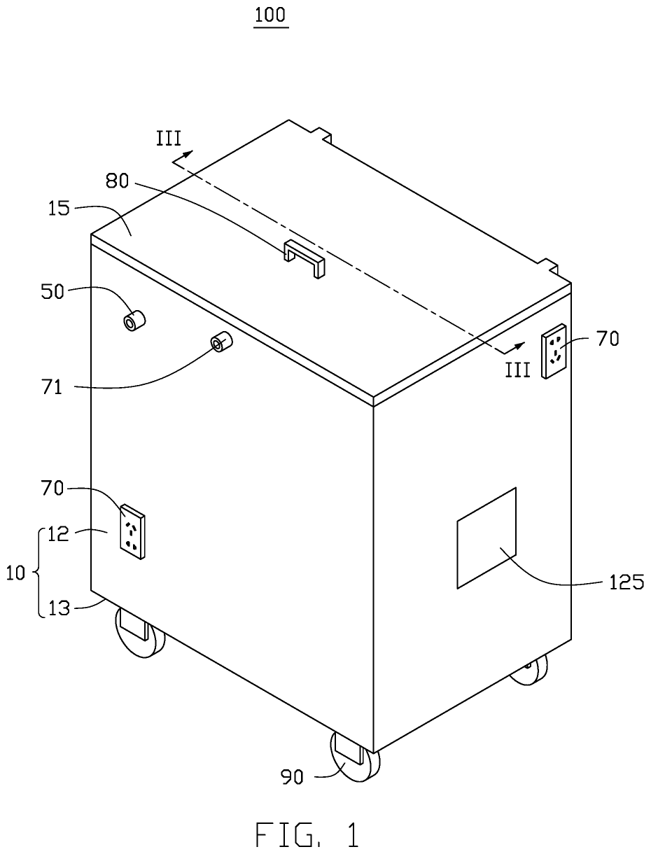

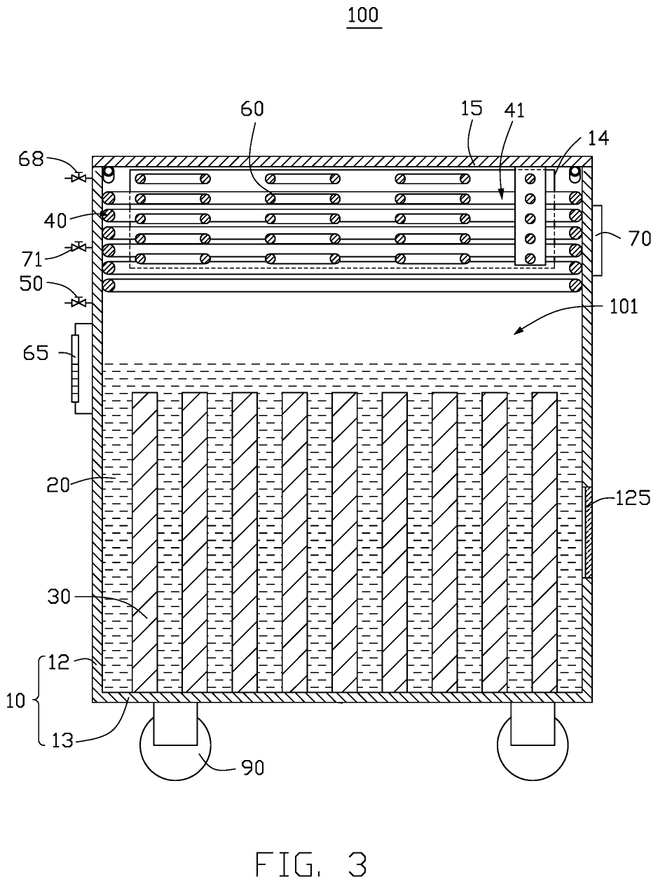

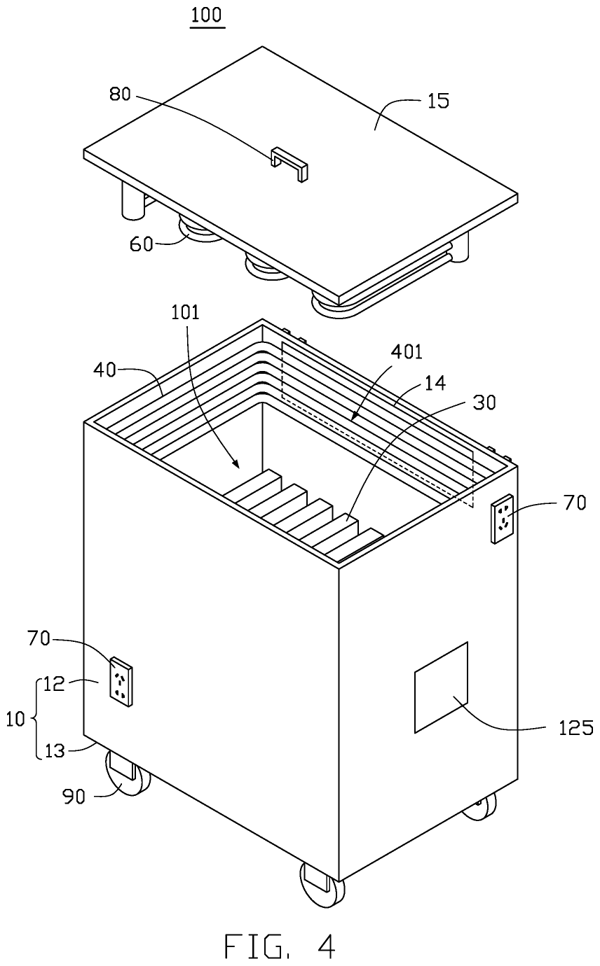

FIG. 1 to FIG. 7 illustrate a two-phase immersion cooling device with a movable second condenser 100 in accordance with an embodiment of the present disclosure.

The two-phase immersion cooling device with movable second condenser 100 includes a box body 10, a cover body 15, a coolant 20, a plurality of heating elements 30, a first condenser 40, and a moveable second condenser 60. The box body 10 defines an accommodating cavity 101. The cover body 15 is adapted to cover the box body 10 to seal the accommodating cavity 101, and the cover body 15 can open the box body 10 to expose the accommodating cavity 101 to the outside. The cover body 15 is detachably or reversibly connected to the box body 10. The cover body 15 can be detachably connected to the box body 10 by means of flange connection, hook connection, bite joint connection, clamp connection, screw connection, etc.

The box body 10 includes a plurality of side walls 12 and a bottom wall 13, the side walls 12 are connected to each other from top to bottom, and the bottom wall 13 is connected to bottom ends of the side walls 12. The plurality of side walls 12 and the bottom wall 13 together form the accommodating cavity 101.

The coolant 20 is disposed in the accommodating cavity 101. The coolant 20 may be, but is not limited to, a liquid having low boiling point and insulating properties. The low boiling point here may be, for example, between about 40-70 degrees or lower than the temperature of heat generated during the operation of the heating elements 30. In other words, the coolant 20 is a substance suitable for direct contact with the heating elements 30, and can effectively absorb the heat generated by the heating elements 30, and boil and evaporate as a result, the present disclosure is not limited to the coolant 20 and its types and physical characteristics. The coolant 20 boils and gasifies rapidly by absorbing the heat generated by the heating element 30, thus reducing the temperature of the heating elements 30.

The heating elements 30 are disposed in the accommodating cavity 101 and are immersed in the coolant 20. The heating elements 30 can be, but are not limited to, a server and components applied in a data center, a battery and an electronic device of a new energy vehicle, an electronic chip and device of a home intelligent digital appliance, an electronic chip and an electronic device applied to digital medical treatment, a chip and an electronic device of edge computing, a chip of quantum computing, a chip of a robot, and heat-generating components of a mechanical equipment or an electronic equipment. The present disclosure is not limited to the type, quantity, size, or scale of the heating element 30.

The first condenser 40 is disposed along the side walls 12. The first condenser 40 is accommodated in the accommodating cavity 101 and is located above the coolant 20 and the heating elements 30. The first condenser 40 is far away from a formed cavity 401 surrounded by the plurality of side walls 12. The cavity 401 is used for the moving up and down of the heating elements 30 during installation, removal, and maintenance. The cavity 401 is a part of the accommodating cavity 101. In the embodiment, the first condenser 40 includes a plurality of condensing tube groups 41, the condensing tube groups 41 are disposed at intervals on the upper part of the box body 10, and at least one condensing tube group 41 is disposed around the circumference of the upper part of the box body 10, or at least one condensing tube group 41 is disposed according to at least one wall surface of the upper part of the box body 10. In other embodiments, the first condenser 40 may also include at least one row and one column of the condensing tube groups 41.

The movable second condenser 60 are fixedly disposed on the cover body 15 and accommodated in the cavity 401. The movable second condenser 60 is used to condense the coolant vapor rising into the cavity 401. The movable second condenser 60 includes at least one row and one column of U-shaped tubular condensing tubes, straight tubular condensing tubes, or snake condensing tubes. When the coolant 20 is gasified to form coolant vapor, the coolant vapor with high thermal energy flows upward to the first condenser 40 and the movable second condenser 60 in the closed accommodating cavity 101, and may be condensed on the first condenser 40 and the movable second condenser 60. The coolant condensate on the first condenser 40 and the movable second condenser 60 falls back into the coolant 20 under the action of gravity, so as to achieve the effective heat dissipation and cooling of the heating element 30.

The movable second condenser 60 enhances the heat transfer capacity of the condenser. If the movable second condenser 60 is not provided in the cavity 401, due to the pressure difference between the coolant vapor located in the cavity 401 and the coolant vapor located at the first condenser 40 being very small, only a small part of the coolant vapor located in the cavity 401 would be condensed on the first condenser 40 disposed on the box body 10, most of the coolant vapor would remain in the cavity 401 and not be condensed effectively, so that the evaporation rate and condensation rate of the coolant 20 in the box body 10 would not reach equality or equilibrium. With the continuous heating by the heating elements 30, after a period of time, the overall temperature in the closed box body 10 gradually increases. The higher the temperature, the greater the pressure in the box body 10. When the pressure in the box body 10 is higher than the pressure outside the box body 10 to form a pressure difference, the vapor in the box body 10 would leak out of the box body 10 under the action of the pressure difference or from the place where the box body 10 is not tightly sealed, or, in order to prevent the box body 10 from exploding, the pressure might be relieved by a safety valve, resulting in the loss of extremely expensive coolant.

In the present disclosure, the movable second condenser 60 can be disposed in the cavity 401 to condense the coolant vapor located in the cavity 401, which effectively increases the heat transfer capacity of the condenser. One of the advantages is that the coolant vapor trapped in the hollow cavity is condensed, so that the evaporation rate and the condensation rate of the coolant 20 in the box body 10 tend to be balanced, the likelihood of a continuous increase of temperature and pressure in the box body 10 caused due to evaporation rate being higher than condensation rate is reduced, the pressure difference inside and outside the box body 10 is reduced, and the leakage loss of extremely expensive coolant vapor is reduced. Another advantage is that the movable second condenser 60 bears part of the condensing capacity of the first condenser 40, which reduces the condensing area required for the first condenser 40, thereby reducing the height of the first condenser 40, reducing the height of the box body 10, and reducing the volume of the two-phase immersion cooling device 100. Such advantages make the two-phase immersion cooling device 100 more compact with low cost.

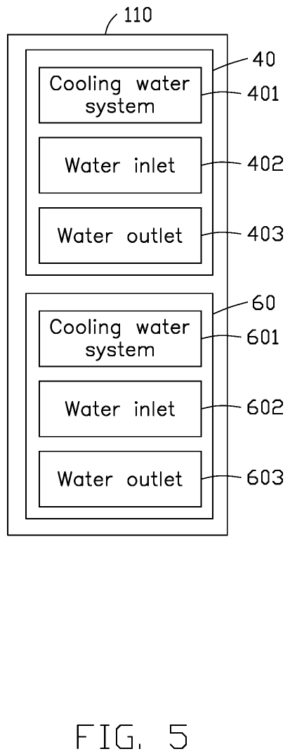

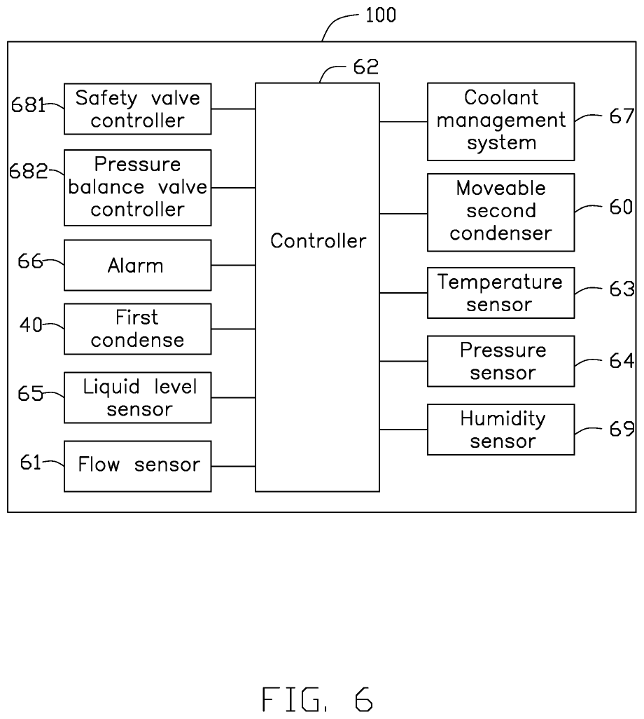

Referring to FIG. 5 and FIG. 6, in one embodiment, the first condenser 40 includes a cooling water system 401, the movable second condenser 60 includes a cooling water system 601. The cooling water system 401 of the first condenser 40 and the cooling water system 601 of the movable second condenser 60 can be operated independently, in series or in parallel, respectively.

The first condenser 40 also includes a water inlet 402 and a water outlet 403 of the cooling water. The movable second condenser 60 also includes a water inlet 602 and a water outlet 603 of the cooling water. The water inlet 402 and the water outlet 403 of the first condenser 40 and the water inlet 602 and the water outlet 603 of the movable second condenser 60 pass through the upper part of the side wall 12 of the box body 10 or the cover body 15, or pass through a rear door 14.

The two-phase immersion cooling device with movable second condenser 100 further includes a controller 62, a plurality of temperature sensors 63, a humidity sensor 69, a plurality of pressure sensors 64, a liquid level sensor 65, a flow sensor 61, an alarm 66, a safety valve controller 681, a pressure balance valve controller 682, and a coolant management system 67.

The temperature sensors 63, the humidity sensor 69, and the pressure sensors 64 are disposed in the accommodating cavity 101 and are respectively used to sense the vapor and liquid temperatures, vapor humidity, and vapor pressures at different positions in the accommodating cavity 101. The controller 62 is electrically connected to the first condenser 40, the movable second condenser 60, the temperature sensor 63, the humidity sensor 69, the pressure sensor 64, the liquid level sensor 65, the flow sensor 61, the alarm 66, the safety valve controller 681, the pressure balance valve controller 682, and the coolant management system 67. The controller 62 can determine the working state of the accommodating cavity 101 according to at least one of the vapor and liquid temperature sensed by the temperature sensor 63, the humidity sensed by the humidity sensor 69, the inlet and outlet temperature of the cooling water in the first condenser 40 or the movable second condenser 60 sensed by the temperature sensor 63, the flow rate of the cooling water in the first condenser 40 or the movable second condenser 60 sensed by the flow sensor 61, and the vapor pressure sensed by the pressure sensor 64. When the vapor temperature sensed by the temperature sensor 63 is higher than a preset temperature, the humidity sensed by the humidity sensor 69 is higher than a preset humidity, or the vapor pressure sensed by the pressure sensor 64 is higher than a preset pressure, the controller 62 controls and adjusts the inlet temperature or the flow rate of the cooling water in the first condenser 40 and/or the movable second condenser 60, to control the condensation capacity of the condenser, so as to achieve the purpose of adjusting and maintaining the balance of operating temperature, pressure, evaporation, and condensation in the box body 10.

The two-phase immersion cooling device with movable second condenser 100 further includes a safety valve 68. The safety valve 68 is disposed on the box body 10 and is electrically connected to the controller 62 through the safety valve controller 681. When the vapor pressure in the accommodating cavity 101 is higher than the preset pressure, the controller 62 is also used to control the safety valve 68 to open until the vapor pressure in the accommodating cavity 101 is lower than the preset pressure, so as to control the operation of the box body 10 under a safe pressure.

The two-phase immersion cooling device with movable second condenser 100 further includes a pressure balance valve 71. The pressure balance valve 71 is disposed on the box body 10 and is electrically connected to the controller 62 through the pressure balance valve controller 682. When the pressure in the accommodating cavity 101 is lower than the atmospheric pressure, in order to facilitate the opening of the cover body 15, the pressure balance valve 71 can be opened manually or through the controller 62 to make the vapor pressure in the accommodating cavity 101 equal to the atmospheric pressure.

The liquid level sensor 65 is disposed on the side wall 12 of the box body 10, and the liquid level sensor 65 is used to detect the liquid level of the coolant 20. The liquid level sensor 65 is connected to the accommodating cavity 101 using the communicator principle. The liquid level of the coolant 20 in the accommodating cavity 101 can be known by observing the liquid level of the liquid level sensor 65.

The controller 62 can control whether the alarm 66 is activated according to the liquid level of the coolant 20 detected by the liquid level sensor 65. When the liquid level detected by the liquid level sensor 65 is lower than a preset height, the controller 62 controls the alarm 66 to give an alarm and controls the coolant management system 67 to replenish the accommodating cavity 101 with coolant 20.

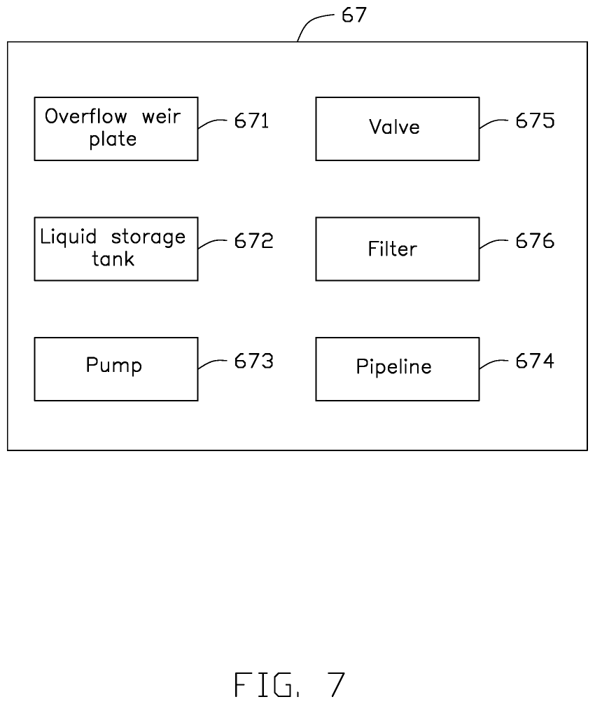

Referring to FIG. 7, the coolant management system 67 includes an overflow weir plate 671, a liquid storage tank 672, a pump 673, a pipeline 674, a valve 675, and a filter 676. The liquid storage tank 672 is separated from a coolant tank by the overflow weir plate 671 at the bottom of the accommodating cavity 101. The pump 673, the pipeline 674, the valve 675, and the filter 676 are disposed inside or outside the box body 10. When the liquid level of the coolant 20 in the accommodating cavity 101 is lower than the preset height, the controller 62 controls the coolant management system 67 to start the pump 673 and control the valve 675 to open, and the coolant 20 can be pumped from the liquid storage tank 672 to the coolant tank at the bottom of the accommodating cavity 101, to keep the coolant level constant, and the excessive pumped coolant 20 flows through the upper end of the overflow weir plate 671 into the liquid storage tank 672.

It can be understood that the number of each of the movable second condenser 60, the temperature sensor 63, the humidity sensor 69, the pressure sensor 64, the liquid level sensor 65, the alarm 66, the coolant management system 67, the safety valve 68, the pressure balance valve 71, and the first condenser 40 can be adjusted according to actual needs, and the number can be 1-24, etc.

The two-phase immersion cooling device with movable second condenser 100 further includes at least one double-faced socket 70. The double-faced socket 70 is disposed on the side wall 12, the cover body 15, or the rear door 14. The inner socket of the double-faced socket 70 is exposed to the accommodating cavity 101, and the outer socket of the double-faced socket 70 is exposed to the outside of the box body 10.

The inner socket of the at least one double-faced socket 70 is electrically connected to the heating element 30, the temperature sensor 63, the humidity sensor 69, the pressure sensor 64, the liquid level sensor 65, and the coolant management system 67. The outer socket of another double-faced socket 70 is electrically connected to the external connecting lines of the heating element 30, the temperature sensor 63, the humidity sensor 69, the pressure sensor 64, the liquid level sensor 65, and the coolant management system 67, so that the heating element 30, the temperature sensor 63, the humidity sensor 69, the pressure sensor 64, the liquid level sensor 65, and the coolant management system 67 are electrically connected to the external elements. The double-faced socket 70 is hermetically connected to the box body 10 or the cover body 15 to seal the accommodating cavity 101.

The two-phase immersion cooling device with movable second condenser 100 also includes a handle 80, and the handle 80 is disposed on the cover body 15 to facilitate opening the cover body 15.

The two-phase immersion cooling device with movable second condenser 100 also includes a power support 81, the power support 81 is connected to the cover body 15 and is used to drive the cover body 15 to open or close. The cover body 15 can be opened to a maximum angle of 180°. The power support 81 can be opened, supported, and closed electrically or pneumatically.

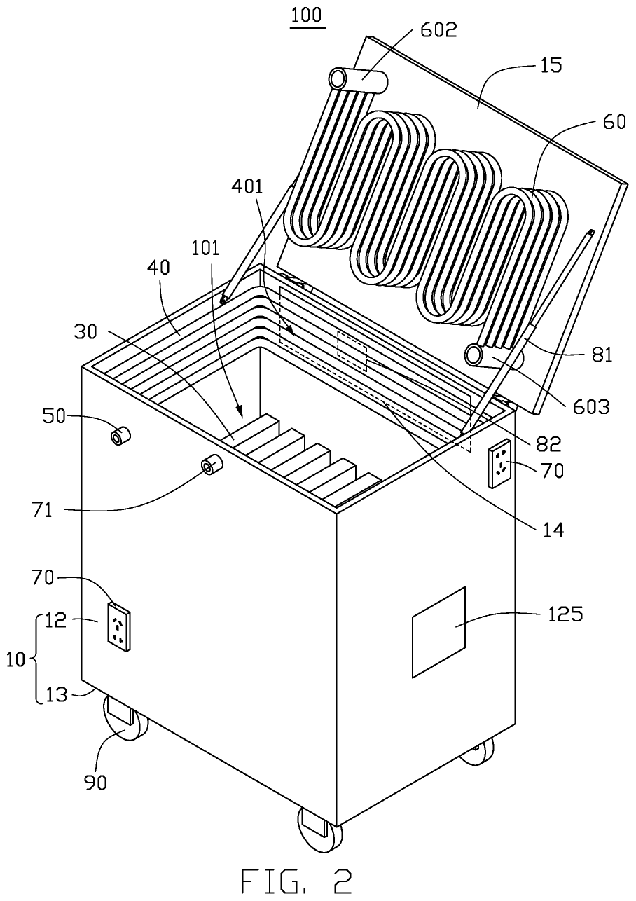

The two-phase immersion cooling device with movable second condenser 100 also includes a power mover 82 (shown in FIG. 2). The power mover 82 is connected to the rear door 14 and is used to move the opening or closing of the rear door 14. The power mover 82 can be opened, supported, and closed electrically or pneumatically.

The two-phase immersion cooling device with movable second condenser 100 further includes a supporting member 90, the supporting member 90 is disposed on the bottom of the box body 10, to support the box body 10. The supporting member 90 may be, but is not limited to, a supporting frame to stabilize the box body 10, or a roller to facilitate the movement of the box body 10.

The two-phase immersion cooling device with movable second condenser 100 further includes a liquid level window 125, and the liquid level window 125 is disposed on the box body 10. The operation state of the heating element 30 and the liquid level height of the coolant 20 can be observed through the liquid level window 125.

The two-phase immersion cooling device with movable second condenser 100 further includes an extracting valve 50, and the extracting valve 50 is disposed on the box body 10.

Before the heating element 30 starts to operate, a vacuum device is used to extract air or other non-condensable vapor in the accommodating cavity 101 through the extracting valve 50, the vacuum device places the accommodating cavity 101 in a closed vacuum state before the operation of the heating element 30 or after the installation, removal, repair, and maintenance of the heating elements 30, so as to ensure the first condenser 40 and the movable second condenser 60 in the accommodating cavity 101 can operate efficiently without non-condensable vapor. In a PID control mode, the pressure or temperature in the accommodating cavity 101 is adjusted to reach a predetermined value by adjusting the flow or inlet temperature of the cooling water in the condenser.

In one embodiment, the two-phase immersion cooling device with movable second condenser 100 further includes a rear door 14, and the rear door 14 is disposed on the box body 10. The rear door 14 is disposed on one side wall 12, and the position of the rear door 14 corresponds to the position of the movable second condenser 60. The side wall 12 of the rear door 14 is not provided with the first condenser 40 when there is a movable second condenser 60 on the rear door 14. The movable second condenser 60 is fixedly disposed on the rear door 14, and the movable second condenser 60 is removed from the accommodating cavity 101 with the movement of the rear door 14. In some embodiments, the rear door 14 is detachably disposed on the box body 10. The rear door 14 can, but is not limited to, make a detachable connection with the box body 10 by means of flange connection, hook connection, bite joint connection, clamp connection, or screw connection.

In some embodiments, the water inlets and the outlets of the first condenser 40 and the movable second condenser 60 can pass through the rear door. In some embodiments, the handle 80 may also be disposed on the rear door.

When a user intends to replace, take, assemble, or repair the heating element 30, the cover body 15 or the rear door 14 can be opened, the movable second condenser 60 is removed from the cavity 401 with the opening of the cover body 15 or the rear door 14, then the heating element 30 can be taken out of the box body 10 or put into the box body 10 through the cavity 401. The first condenser 40 and the movable second condenser 60 can also be combined into a third condenser 110, the third condenser 110 is disposed on the cover body 15 or the rear door 14 and accommodated in the accommodating cavity 101, and the third condenser 110 may be removed from the cavity 401 together with the opening of the cover body 15 or the rear door 14.

Those skilled in the art can understand that the above embodiments are only examples, in which the features of different embodiments can be combined with each other to obtain implementations that are easily conceivable according to the disclosure of the present disclosure but are not clearly indicated in the drawings.

Those skilled in the art should understand that the above description and the embodiments of the present disclosure shown in the drawings are only examples and do not limit the present disclosure. The purpose of the present disclosure has been completely and effectively achieved. The functions and structural principles of the present disclosure have been shown and explained in the embodiments. Without departing from the principles, the implementation of the present disclosure may have any deformation or modification.

What is claimed is:

1. A two-phase immersion cooling device with movable second condenser, the two-phase immersion cooling device comprising:
a box body comprising a plurality of side walls connected to each other from top to bottom and a bottom wall, the bottom wall connected to one end of each of the plurality of side walls, the plurality of side walls and the bottom wall jointly forming an accommodating cavity, and a bottom of the accommodating cavity being configured to contain a coolant;
a plurality of heating elements disposed in the accommodating cavity and adapted to be immersed in the coolant;
a first condenser disposed along at least one of the plurality of side walls, received in the accommodating cavity, and located above the coolant and the plurality of heating elements, the first condenser being far away from a cavity surrounded by the plurality of side walls;
a cover body covering the box body to seal the accommodating cavity and being expandable on the box body to expose the accommodating cavity to an exterior environment, wherein the at least one movable second condenser is fixedly disposed on the cover body or a rear door located on an upper part of the box body, the at least one movable second condenser is received in the cavity, and the at least one movable second condenser is removed from the accommodating cavity with a movement of the cover body or the rear door.

2. The two-phase immersion cooling device according to claim 1, wherein the first condenser and the at least one movable second condenser are combined into a third condenser, the third condenser is disposed on the cover body or the rear door.

3. The two-phase immersion cooling device according to claim 1, wherein the cover body is detachably or reversibly connected to the box body, or the rear door is detachably connected to the box body.

4. The two-phase immersion cooling device according to claim 1, wherein the two-phase immersion cooling device further comprises a power support, the power support is connected to the cover body and used to drive the cover body to open or close, and the cover body is opened to a maximum angle of 180° .

5. The two-phase immersion cooling device according to claim 1, wherein the first condenser comprises a first cooling water system, the at least one movable second condenser comprises a second cooling water system, the first cooling water system of the first condenser and the second cooling water system of the at least one movable second condenser are operated independently, in series or in parallel, respectively.

6. The two-phase immersion cooling device according to claim 1, wherein each of the first condenser and the at least one movable second condenser comprises a water inlet of the cooling water and a water outlet of the cooling water, the water inlet and the water outlet pass through the upper part of the box body, the cover body, or the rear door.

7. The two-phase immersion cooling device according to claim 1, further comprising at least one sensor disposed in the accommodating cavity, wherein the at least one sensor comprises at least one of a temperature sensor, a humidity sensor, a pressure sensor, a flow sensor, and a liquid level sensor, the at least one sensor is configured for sensing at least one of a vapor temperature, a liquid temperature, vapor humidity, a vapor pressure, a liquid level height of the coolant, an inlet temperature, an outlet temperature, and a flow rate of the cooling water of each of the first condenser and the at least one movable second condenser in the accommodating cavity.

8. The two-phase immersion cooling device according to claim 7, wherein the liquid level sensor is disposed on the box body or in the box body, the liquid level sensor is connected to the accommodating cavity, and the liquid level sensor detects the liquid level height of the coolant.

9. The two-phase immersion cooling device according to claim 7, further comprising a controller, wherein the controller is electrically connected to the at least one movable second condenser, the at least one sensor, and the first condenser, when the at least one sensor senses the vapor temperature in the accommodating cavity is higher than a preset temperature or the vapor pressure in the accommodating cavity is higher than a preset pressure, the controller controls and adjusts the inlet temperature and the flow rate of the cooling water in the at least one movable second condenser or the first condenser.

10. The two-phase immersion cooling device according to claim 9, further comprising an alarm, a liquid level sensor, and a coolant management system, wherein the controller is electrically connected to the liquid level sensor, the alarm, and the coolant management system, when the liquid level height of the coolant detected by the liquid level sensor is lower than a preset height, the controller controls the alarm to give an alarm, and controls the coolant management system to replenish the coolant into the accommodating cavity.

11. The two-phase immersion cooling device according to claim 10, wherein the coolant management system comprises an overflow weir plate, a liquid storage tank, a pump, a pipeline, a valve, and a filter.

12. The two-phase immersion cooling device according to claim 1, wherein the plurality of heating elements comprises a server applied to a data center, a battery or an electronic device applied to a new energy vehicle, an electronic chip or a device applied to a home intelligent digital appliance, an electronic chip or an electronic device applied to a digital medical treatment, an electronic chip or an electronic device for digital medical treatment, a chip and an electronic device for edge computing, a chip for quantum computing, and a heating component applied to mechanical equipment or electronic equipment.

13. The two-phase immersion cooling device according to claim 1, further comprising at least one double-faced socket hermetically disposed on the box body or the cover body.

14. The two-phase immersion cooling device according to claim 1, further comprising an extracting valve, wherein the extracting valve is disposed on the box body or the cover body, the extracting valve is connected to a vacuum device to extract non-condensable vapor in the accommodating cavity.

15. The two-phase immersion cooling device according to claim 1, further comprising a handle disposed on the cover body or the rear door.

16. The two-phase immersion cooling device according to claim 1, further comprising a supporting member, wherein the supporting member is disposed on a bottom of the box body, and the supporting member is a supporting frame or a roller.

17. The two-phase immersion cooling device according to claim 1, further comprising a safety valve, wherein when vapor pressure in the accommodating cavity is higher than a preset vapor pressure, the safety valve is opened until the vapor pressure in the accommodating cavity is lower than the preset vapor pressure.

18. The two-phase immersion cooling device according to claim 1, wherein the at least one movable second condenser is any one of a U-shaped tube condenser, a straight tube condenser, and a snake tube condenser.

19. The two-phase immersion cooling device according to claim 1, wherein the cover body and the rear door are detachably connected to the box body by flange connection, hook connection, bite joint connection, clamp connection, or screw connection.

20. The two-phase immersion cooling device according to claim 1, further comprising a pressure balance valve, wherein when vapor pressure in the accommodating cavity is lower than an atmospheric pressure, the pressure balance valve is opened until the vapor pressure in the accommodating cavity is equal to the atmospheric pressure.

21. The two-phase immersion cooling device according to claim 1, wherein the two-phase immersion cooling device further comprises a power mover, the power mover is connected to the rear door and used to drive the rear door to open or close.
